(19) United States
(12) Patent Application Publication
(10) Pub. No.: US 2022/0048763 A1
(43) Pub. Date: Feb. 17, 2022

(54) MANUFACTURING A CORROSION TOLERANT MICRO-ELECTROMECHANICAL FLUID EJECTION DEVICE

(71) Applicant: Hewlett-Packard Development Company, L.P., Spring, TX (US)

(72) Inventors: Stanley J Wang, Corvallis, OR (US); Anthony M Fuller, Corvallis, OR (US)

(73) Assignee: Hewlett-Packard Development Company, L.P., Spring, TX (US)

(21) Appl. No.: 17/297,423

(22) PCT Filed: Apr. 29, 2019
(86) PCT No.: PCT/US2019/029632

§ 371 Date: May 26, 2021

(51) Int. Cl. B81C 1/00; B41J 2/16

(52) U.S. Cl. CPC B81C 1/00801; B41J 2/1628; B41J 2/162

(57) ABSTRACT

Aspects are directed to techniques for fabricating a microfluidic device on a substrate. In a particular example, a method of manufacturing a microfluidic device includes growing a thermal oxide layer on a substrate and depositing a dielectric layer, including doped a dielectric film, over the thermal oxide layer. Next, an aperture defined by a dielectric wall which forms part of the dielectric layer is formed in the dielectric layer by selectively removing the dielectric film. Finally, the aperture is sealed with a sealing film to prevent the dielectric film from being exposed to a fluid contained in the aperture. The sealing film may be of an electrically insulating material resistive to corrosive attributes of the fluid contained in the aperture.

### BACKGROUND

A microfluidic device including a fluid ejection channel defined by a fluid barrier and an orifice, or nozzle, for containing and/or passing fluids, and further including micro-electromechanical systems (MEMS) and/or electronic circuitry may be fabricated on a silicon substrate and included in a fluid ejection system. Various microfabrication techniques used for fabricating semiconductor devices may be used to manufacture such microfluidic devices.

### BRIEF DESCRIPTION OF FIGURES

Various examples may be more completely understood in consideration of the following detailed description in connection with the accompanying drawings, in which:

FIG. 1 illustrates an example flowchart describing a method for manufacturing a microfluidic device, consistent with the present disclosure;

FIGS. 2A-2D illustrate an example microfluidic device at various stages of the manufacturing process, consistent with the present disclosure;

FIG. 3 illustrates an example microfluidic device, consistent with the present disclosure; and

FIGS. 4A and 4B illustrate an example cross-section of a microfluidic device having multiple apertures, consistent with the present disclosure.

While various examples discussed herein are amenable to modifications and alternative forms, aspects thereof have been shown by way of example in the drawings and will be described in detail. It should be understood, however, that the intention is not to limit the disclosure to the particular examples described. On the contrary, the intention is to cover all modifications, equivalents, and alternatives falling within the scope of the disclosure including aspects defined in the claims. In addition, the term “example” as used throughout this application is only by way of illustration, and not limitation.

### DETAILED DESCRIPTION

The present disclosure relates to a process of manufacturing a microfluidic device including a fluid seal structure. Micro-electro mechanical systems (MEMS) and circuitry may be integrated into the same microfluidic device (e.g., formed on the same substrate), and the microfluidic device may include a plurality of microfluidic architectural features. An example of a microfluidic architectural feature that may be included in a microfluidic device is an aperture, which may contain fluid, and/or permit the passage/ejection of fluid from orifices, or fluid holes, included in a fluid ejection system of which the microfluidic device is a part. Moreover, the aperture may be sealed with a film to protect the MEMS and circuitry included therein from being exposed to the corrosive properties of the fluid contained in the aperture, passing there through, and/or being ejected therefrom.

Another example of a microfluidic architectural feature that may be included in a microfluidic device is an aperture, or fluid port. In some examples, the aperture may be an area in which the microfluidic device was cleared of its dielectric layer which may include a dielectric film. A non-limiting example of such a microfluidic device may include a printhead, or printhead die, while a non-limiting example of a fluid contained in, passing through, and/or being ejected from a microfluidic device may include fluid. As used herein, the term ‘collocated’ may refer to or include a MEMS microfluidic device and integrated circuitry being disposed on the same substrate, being within a threshold distance of each other, and vertically and/or horizontally abutting each other.

Certain aspects of the present disclosure are directed to a method including growing a thermal oxide layer on a substrate and depositing a dielectric layer over the thermal oxide layer, the dielectric layer including a doped dielectric film. The method further includes forming an aperture in the dielectric layer, the aperture being defined by a dielectric wall which forms part of the dielectric layer, by selectively removing the dielectric film, and sealing the aperture in the dielectric layer with a sealing film that protects the dielectric layer from corrosive attributes of a fluid contained in the aperture from contacting the doped dielectric film.

Additional aspects of the present disclosure are directed to a method of manufacturing an apparatus to receive a fluid having corrosive attributes. The method includes forming a first region of the apparatus with logical circuits formed thereon and including a doped dielectric film by growing a thermal oxide layer on a substrate and depositing a doped dielectric film over the thermal oxide layer. In some specific examples, metal layer may be deposited over the doped dielectric film. The method further includes forming a second region including a fluid port to receive fluid by selectively removing a portion of the doped dielectric film in the fluid port, the fluid port being defined by a wall of the doped dielectric film, and protecting the doped dielectric film of the first region from the corrosive attributes of the fluid by depositing an un-doped dielectric film over the wall of the doped dielectric film.

Additional non-limiting examples are directed to a method of manufacturing an apparatus including forming a monolithic integrated circuit with logical circuits formed thereon and including a doped dielectric film by growing a thermal oxide layer on a substrate, depositing the doped dielectric film over the thermal oxide layer, and depositing a metal layer over the doped dielectric film. The method also includes forming a portion of a microfluidic device collocated on the apparatus with the integrated circuit, the portion of the microfluidic device including a fluid port, by removing the doped dielectric film in a location of the microfluidic device and including the fluid port, the fluid port being defined by a wall of the doped dielectric film. Furthermore, the method may include protecting the doped dielectric film of the monolithic integrated circuit from corrosive attributes of the fluid by depositing an un-doped dielectric film over the wall of the doped dielectric film.

Certain examples and/or variations of these examples may be practiced without all the specific details given below. In other instances, well known features have not been described in detail so as not to obscure the description of the examples herein. For ease of illustration, the same reference numerals may be used in different diagrams to refer to the same elements or additional instances of the same element. Also, although aspects and features may in some cases be described in individual figures, it will be appreciated that features from one figure or example can be combined with features of another figure or example even though the combination is not explicitly shown or explicitly described as a combination.

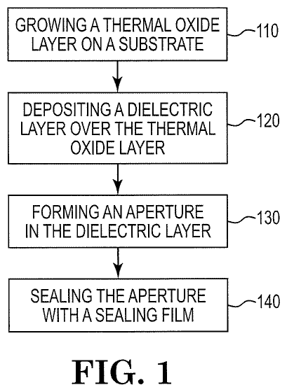

Turning now to the figures, FIG. 1 illustrates an example flowchart describing a method for manufacturing a microfluidic device, consistent with the present disclosure. Particularly, FIG. 1 illustrates at 110, growing a thermal oxide layer on a substrate. As used herein, a thermal oxide refers to or includes a layer of oxide, such as a silicon dioxide, diffused into the surface of a wafer. Silicon can be oxidized with water vapor or molecular oxygen as an oxidant, referred to as wet or dry oxidation, respectively, and thermal oxidation may be performed in a furnace at temperatures ranging from about 800° C. to 1200° C. Thermal oxidation may be applied to different materials, but may include the oxidation of silicon substrates to produce silicon dioxide. In some examples, the thermal oxide may include a field oxide. As used herein, a field oxide refers to or includes a relatively thick oxide, such as for instance between 100 and 500 nm.

At 120, the method includes depositing a dielectric layer over the thermal oxide layer. In various examples, the dielectric layer includes a doped dielectric film, and an un-doped film. For instance, in various examples, depositing the dielectric layer includes depositing a polysilicon layer over the thermal oxide and before a doped dielectric film. In some non-limiting examples, the dielectric film may be borophosphosilicate glass (BPSG), and the un-doped dielectric film includes an un-doped glass, although examples are not so limited and other doped dielectric films and un-doped dielectric films are contemplated.

At 130, the method includes forming an aperture in the dielectric layer. The aperture may be defined by a dielectric wall which forms part of the dielectric layer, and may be formed. The aperture may be formed by selectively removing the dielectric film by dry etching the doped dielectric film to a termination point in the thermal oxide layer.

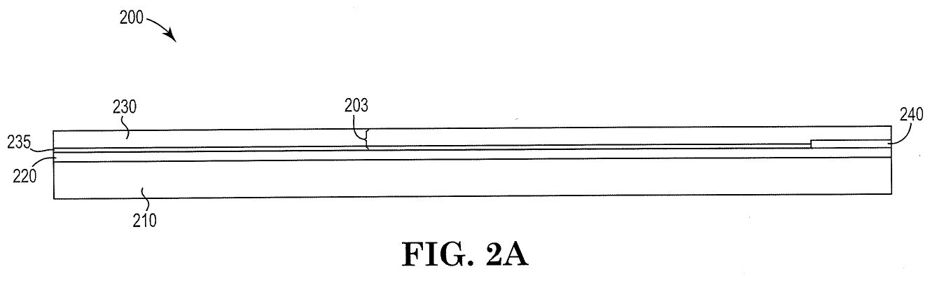

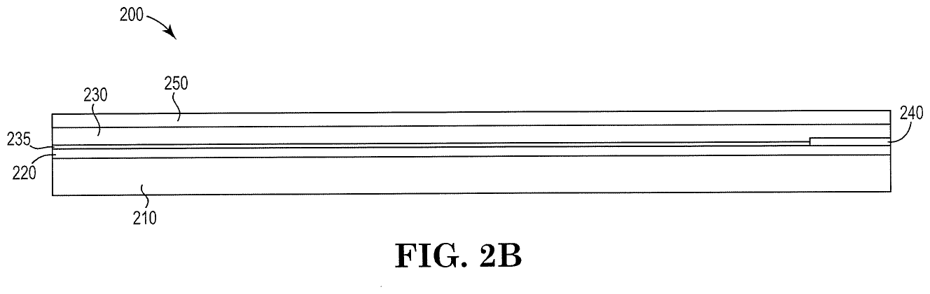

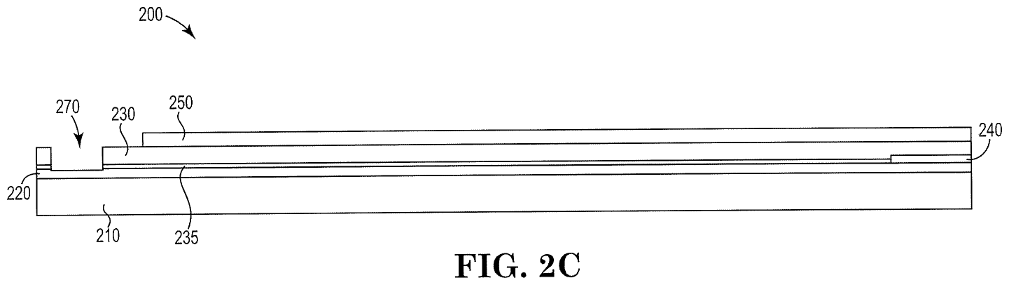

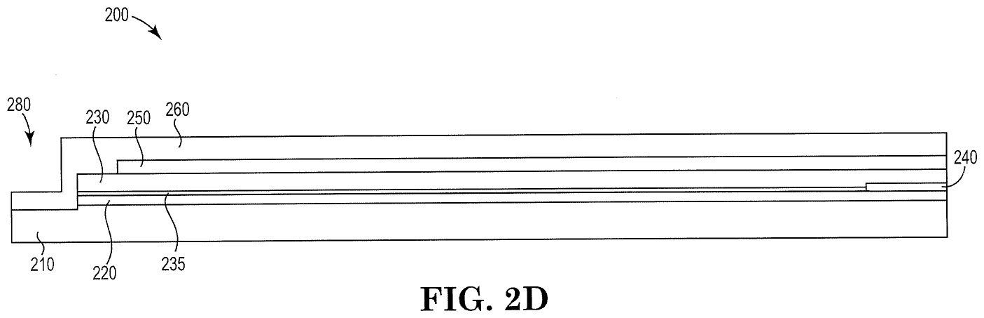

Various approaches may be used to remove portions of the doped dielectric film. For instance, forming the aperture, or removing dielectric from the fluid port as discuss further with regards to FIGS. 2-4, may include selectively removing the portion of the doped dielectric film in the fluid port using a selective mask and applying an etching process. The etching process used to remove the portion of the doped dielectric film in the fluid port may be one of plasma etching, wet etching, dry etching, and contact etching, among other non-limiting examples. In other examples, the method may include selectively removing the portion of the doped dielectric film in the fluid port by using a mask to selectively etch the doped dielectric film. In various examples, forming the aperture in the dielectric layer may include dry etching the doped dielectric to a termination point in the thermal oxide layer and/or selectively removing the doped dielectric in the aperture by contact etching the doped dielectric while patterning the metal layer. In other examples, forming the aperture in the dielectric layer may include selectively removing the doped dielectric film and an un-doped dielectric film in the dielectric layer to a termination point in the thermal oxide layer.

At 140, the method includes sealing the aperture in the dielectric layer with a sealing film that prevents the dielectric film from being exposed to a fluid contained in the aperture. In various examples, sealing the aperture in the dielectric layer may include depositing an un-doped dielectric film over the dielectric wall. Moreover, sealing the aperture in the dielectric layer may include depositing an un-doped dielectric film that is electrically insulating and resistive to the corrosive attributes of the fluid contained in the aperture. In some specific and non-limiting examples, sealing the aperture in the dielectric layer may include depositing tetraethyl orthosilicate (TEOS) over the dielectric wall.

In some specific, yet non-limiting examples, a microfluidic device, or multiple fluidic devices manufactured in accordance with the method described in FIG. 1 may be included in, for instance, a printhead. The printhead may include a fluid ejection system in which fluid ports receive fluid, such as ink or non-ink fluids including polymeric materials and/or biologic materials, before the fluid is ejected therefrom. The combination of a microfluidic device included in a printhead and the fluid ejection system included in the microfluidic device shall henceforth be referred to as, ‘a printhead assembly’. Such printhead assembly may be included in, for instance, a printing system such as a printer.

FIGS. 2A-2D illustrate an example microfluidic device at various stages of the manufacturing process, consistent with the present disclosure. For instance, FIG. 2A illustrates microfluidic device 200 in an early stage of being manufactured by a process consistent with the above-described method. In a number of examples, substrate 210, which may be of silicon (Si) preconditioned with a dopant, serves as the area upon which metal-oxide semiconductor (MOS) circuitry and/or MEMS which may be included in a microfluidic device, such as a printhead, are fabricated. A thermal oxide layer 220 may be grown on the substrate 210. A dielectric layer 203 may be deposited over the thermal oxide layer 220. The thermal oxide layer 220 provides isolation between the dielectric layer 203 and the substrate 210. In more specific examples, after growing the thermal oxide layer 220, gate control for the circuitry included in the microfluidic device may be achieved by depositing a polysilicon layer, or polygate 240 between the thermal oxide layer 220 and the dielectric layer 203.

In various examples, dielectric layer 203 may include a doped dielectric film 230 which, by gettering ionic contaminants that may migrate to the interface of the various layers and/or to the active region(s) of the printhead die, helps maintain/preserve the operation of the MEMS circuitry integrated into printhead die. In some examples, the doped dielectric film 230 may be borophosphosilicate glass (BPSG). In such examples, there may be an un-doped glass film 235 beneath the dielectric film 230 to prevent dopant migration into active areas of the microfluidic device. For instance, the un-doped glass film 235 may prevent the migration of Boron from the BPSG included in the dielectric film 230. As illustrated in FIG. 2B and consistent with the above-described method, a (first) metal layer 250 may be deposited directly over the doped dielectric film 230.

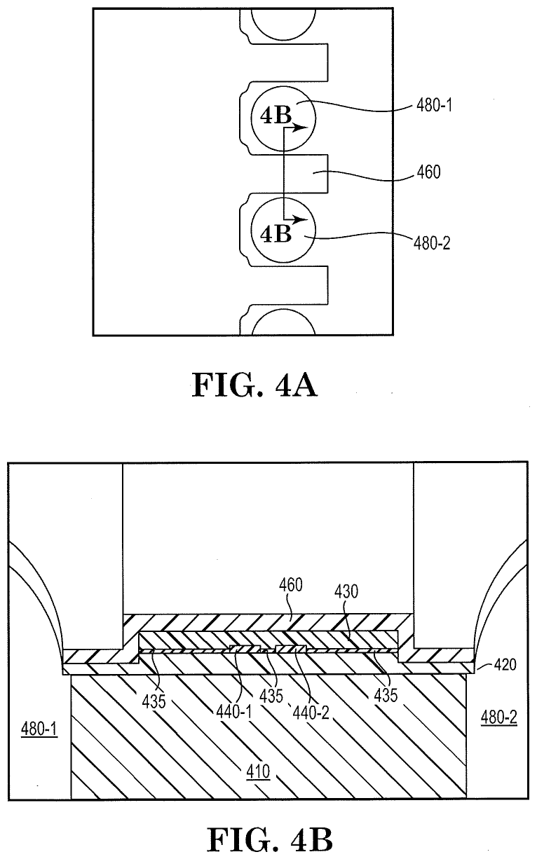

FIG. 2C illustrates a channel, or moat 270, which is one example of a microfluidic architectural feature that may be included in microfluidic device 200. The moat 270 may be formed by identifying area(s) of the microfluidic device 200 on which MEMS are to be located. A process, such as contact etching, may be used to selectively remove the doped dielectric film 230 from the identified area(s), as discussed with regards to FIG. 1. In some examples, the moat 270 may be disposed between MEMS and circuitry, collocated on the same substrate 210, as discussed further with regards to FIG. 4.

FIG. 2D illustrates an aperture 280, which is another example of a microfluidic architectural feature that may be included in microfluidic device 200. Manufacturing a microfluidic device including MEMS and circuitry monolithically integrated on the same substrate 210 using some of the same processes used to manufacture planar integrated circuits, including but not limited to various forms of etching and photolithography, exposes the doped dielectric film included in the dielectric layer 203 to the corrosive properties of the fluid passing through the aperture 280. The sealing film 260, which in a number of examples may be tetraethyl orthosilicate (TEOS), is an electrically insulating material resistive to the corrosive attributes of the fluid contained in the aperture 280. The sealing film 260 protects the microfluidic device 200 from the corrosive attributes included therein by forming a boundary between the fluid and the MEMS/circuitry included in the microfluidic device 200. Sealing film 260 may directly cover the first metal layer 250 and the portion of the doped dielectric film 230 selectively removed by the same contact etching process used to form moat 270. In some examples, the sealing film 260 may also directly cover the substrate 210.

In various examples, forming the monolithic integrated circuit may include depositing a polysilicon layer over the thermal oxide and before the doped dielectric film. Moreover, forming the monolithic integrated circuit may include depositing a polysilicon layer including an overlay region of polysilicon extending beyond the wall of the doped dielectric film, and removing the overlay region of polysilicon and the doped dielectric from the fluid port. Additionally and/or alternatively, forming the monolithic integrated circuit may include selectively removing the portion of the doped dielectric film in the fluid port by, using a selective mask and contact etch process, removing the doped dielectric film from the fluid port, patterning the metal layer over the doped dielectric film, and etching both the metal layer and doped dielectric film.

Additionally and/or alternatively, the sealing film 260 may be used to backfill the moat 270, in some instances completely, before the printhead die is planarized by, for example, a chemical-mechanical planarization (CMP) and/or resist etch back process. The result of such processing is a microfluidic device including an area in which the dielectric film 230 is present, and an area in which the dielectric film 230 has been removed, backfilled with the sealing film 260, and then planarized.

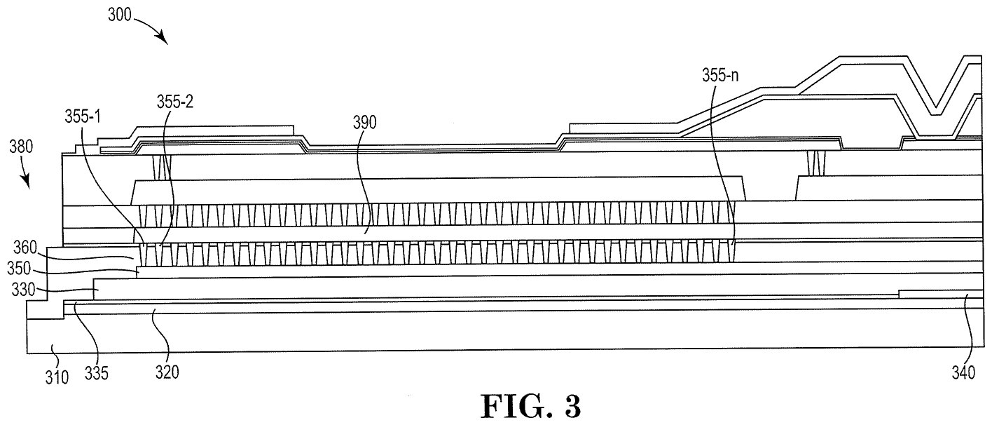

FIG. 3 illustrates an example microfluidic device, consistent with the present disclosure. In additional examples and/or implementations, particularly those in which access to tungsten plugs for establishing electrical connectivity between the various layers of a printhead die may be lacking, selective contact etching or similar processes may be used to selectively remove the dielectric film included in dielectric layer 330 and/or sealing film 360 from areas in/through which electrical contact is to be established between metal layers of the microfluidic device. Metal interconnects 355-1, 355-2 . . . 355-n (collectively “metal interconnects 355”) may be patterned through sealing film 360 by selectively removing the sealing film 360 by using, for instance, contact etching. The metal interconnects 355 may establish electrical contact between a first metal layer 350 and a second metal layer 390. As the second metal layer 390 is deposited over the now contact etched sealing film 360, the orifices created by the contact etching process may be filled with the second metal layer 390 as it is deposited directly over the sealing film 360. In examples in which a moat is formed in the printhead die, such as moat 270 depicted in FIG. 2C, the first metal layer 250 is completely removed from moat 270 during the removal process. In such example, again, contact etching may be used for the removal.

In various examples, to completely remove a metal layer and/or the dielectric layer/sealing film from targeted location(s) as described above, over-etching may be used. Over-etching may result from etching processes not being 100% selective for a particular material. In FIG. 3, the over-etching of, for example, the sealing film 360 may occur because the etchant used to perform the (contact) etching process used to selectively remove portions of the sealing film 360 is not 100% selective for the material, for instance TEOS, of which the sealing film 360 is made.

To overcome etching processes not being 100% selective for a particular material, and in an effort to reduce the negative effects of over-etching such as the uneven thinning of the dielectric layer/sealing film and/or a metal layer no longer being planar after etching is complete, a polygate layer 340 for controlling the integrated circuitry sitting over the thermal oxide layer 320 may be patterned early in the formation of the microfluidic device. If the polygate layer 340 is patterned early in the manufacturing process so it underlies the MEMS area of the printhead, in addition to controlling the gates of the integrated circuitry, the polygate layer 340 will also raise the surface reached by the metal interconnects 355 when the dielectric film 330 and/or sealing film 360 is being removed, thereby increasing the ability to minimize the over-etching of a particular layer. Materials with different etch rates and an appropriate etchant may be used to increase the accuracy of the etching process. For instance, boron trichloride (BCl₃) may be used as an etchant given the difference in etch rates between the polysilicon of the polygate and the boron included in the BPSG of the dielectric film.

FIGS. 4A and 4B illustrate an example cross-section of a microfluidic device having multiple apertures, consistent with the present disclosure. More particularly, FIGS. 4A and 4B illustrate a microfluidic device, or multiple such microfluidic devices, as may be included in, for example, an printhead, a portion of which is illustrated in FIG. 4A. The printhead may include a fluid ejection system in which fluid ports receive fluid, such as ink, before the fluid is ejected therefrom onto, for instance, print media. The combination of a microfluidic device included in a printhead and the fluid ejection system included in the microfluidic device may be referred to as, a printhead assembly. Such a printhead assembly may be included in, for instance, an inkjet printing system such as a printer (not shown).

The printing system may further include a fluid supply assembly, a mounting assembly, a media transport assembly, an electronic controller, and a power supply for providing power to the various MEMS and integrated circuitry included in the printing system. Moreover, fluid ejection devices, in some instances fluid ports, apertures, moats, and the like, included in the fluid ejection system of the printhead may be implemented as fluid drop jetting printhead dies for ejecting drops of fluid through a plurality of fluid holes 480-1, 480-2, toward print media so as to print onto the print media. The fluid holes may also be referred to herein as nozzles or orifices. The fluid holes 480-1, 480-2 may be arranged in a column, or as an array such that properly sequenced ejections of fluid through the fluid holes 480-1, 480-2 cause characters, symbols, and/or other graphics/images to be printed on the print media. The print media included in the print system may be any type of suitable sheet or roll material, including but not limited to paper, card stock, transparencies, Mylar, and the like.

A printhead included in a printhead assembly may be supplied fluid from a supply assembly (not shown) included in a print system of which the printhead assembly is a part. The fluid supply assembly may include a reservoir for storing fluid. Fluid flows from the reservoir to the printhead assembly and through the fluid holes 480-1, 480-2. With corrosive fluids being disposed within fluid holes 480-1, 480-2, the integrated circuits disposed between the fluids are susceptible to corrosion. Accordingly, a portion of the dielectric material may be removed from the integrated circuit and coated with a sealing film, so as to protect the integrated circuit from the corrosive properties of the fluid.

FIG. 4B illustrates a cross section view of the printhead structure along the line illustrated between fluid holes 480-1 and 480-2. As illustrated in FIG. 4B, each fluid hole 480-1, 480-2 may be separated by a substrate 410, discussed with regards to FIGS. 2 and 3. In a number of examples, substrate 410, which may be of silicon (Si) preconditioned with a dopant, may form the area upon which metal-oxide semiconductor (MOS) circuitry is fabricated. For instance, referring to the cross-sectional view of FIG. 4B, a thermal oxide layer 420 may be grown on the substrate 410. A doped dielectric film 430 may be deposited over the thermal oxide layer 420. As described herein, the thermal oxide layer 420 provides isolation between the doped dielectric film 430 and the substrate 410. In more specific examples, after growing the thermal oxide layer 420, gate control for the circuitry included in the microfluidic device may be achieved by depositing a polysilicon layer, or polygate 440-1, 440-2 between the thermal oxide layer 420 and the doped dielectric film 430. Additionally, as illustrated, an un-doped glass film 435 may be disposed beneath the doped dielectric film 430 to prevent dopant migration into active areas of the integrated circuit.

As discussed with regards to FIG. 2C, a channel, or moat 470-1, 470-2, may be included in which dielectric material is removed, and subsequently coated with a protective film of a corrosive resistant an electrically insulating material, of which TEOS is provided as a non-limiting example. The moat 470-1, 470-2 may be formed by selectively removing the doped dielectric film 430 from the identified area(s), such as by using contact etching. Although FIG. 4 illustrates the result of an etching process terminating at a termination point in the thermal oxide layer 420, additional examples are contemplated. For instance, the etching process may terminate at a termination point in the substrate 410, at the top surface of the thermal oxide layer 420 (e.g., terminating at the thermal oxide layer), or terminate at the top surface of the substrate (e.g., terminating at the substrate layer).

In some examples, the moat 470-1, 470-2 may be disposed between MEMS and circuitry, collocated on the same substrate 410. As the fluid holes 480-1, 480-2 of the MEMS may be collocated with the integrated circuit, a sealing film of an electrically insulating and corrosive resistant may be deposited in the moat to the edge of the fluid holes 480-1, 480-2. For instance, a sealing film 460 may be deposited over the etched doped dielectric film, as discussed with regards to FIGS. 1-3.

Terms to exemplify orientation, such as upper/lower, left/right, top/bottom and above/below, may be used herein to refer to relative positions of elements as shown in the figures. It should be understood that the terminology is used for notational convenience only and that in actual use the disclosed structures may be oriented different from the orientation shown in the figures. Thus, the terms should not be construed in a limiting manner.

The various terminology used in the Specification (including claims) connote a plain meaning in the art unless otherwise indicated. As examples, the Specification describes and/or illustrates aspects useful for implementing the claimed disclosure by way of various circuits or circuitry which may be illustrated as or using terms such as blocks, modules, device, system, unit, controller, layers, interconnects, and/or other circuit-type depictions. For example, reference numerals 210 and 220 of FIG. 2A depict layer as described herein. As another example, reference numerals 355-1, 355-2 . . . 355-n of FIG. 3 depict interconnects as described herein. As another example, where the Specification may make reference to a “first [type of structure]”, a “second [type of structure]”, etc., where the [type of structure] might be replaced with terms such as [“circuit”, “circuitry”, “layer”, “interconnects”, and others], the adjectives “first” and “second” are not used to connote any description of the structure or to provide any substantive meaning; rather, such adjectives are merely used for English-language antecedence to differentiate one such similarly-named structure from another similarly-named structure (e.g., “first circuit configured to convert . . . ” is interpreted as “circuit configured to convert . . . ”).

Based upon the above discussion and illustrations, it may be recognized that various modifications and changes may be made without strictly following the various examples and applications illustrated and described herein. For example, methods as depicted in the Figures may involve steps carried out in various orders, with aspects of the disclosure herein retained, or may involve fewer or more aspects. Such modifications do not depart from the true spirit and scope of various aspects of the disclosure, including aspects set forth in the claims.

What is claimed is:

1. A method comprising:
growing a thermal oxide layer on a substrate;
depositing a dielectric layer over the thermal oxide layer, the dielectric layer including a doped dielectric film;
forming an aperture in the dielectric layer, wherein the aperture is defined by a dielectric wall which forms part of the dielectric layer, by selectively removing the dielectric film; and
sealing the aperture in the dielectric layer with a sealing film that prevents the dielectric film from being exposed to a fluid contained in the aperture.

2. The method of claim 1, wherein sealing the aperture in the dielectric layer includes depositing an un-doped dielectric film over the dielectric wall.

3. The method of claim 1, wherein sealing the aperture in the dielectric layer includes depositing an un-doped dielectric film that is electrically insulating and resistive to corrosive attributes of the fluid contained in the aperture.

4. The method of claim 1, wherein sealing the aperture in the dielectric layer includes depositing tetraethyl orthosilicate (TEOS) over the dielectric wall.

5. The method of claim 4, wherein forming the aperture in the dielectric layer includes dry etching the doped dielectric film in the dielectric layer to a termination point in the thermal oxide layer.

6. The method of claim 1, wherein forming the aperture in the dielectric layer includes selectively removing the doped dielectric film in the aperture by etching.

7. The method of claim 1, wherein forming the aperture in the dielectric layer includes selectively removing the doped dielectric film and an un-doped dielectric film in the dielectric layer to a termination point in the thermal oxide layer.

8. A method of manufacturing an apparatus to receive a fluid having corrosive attributes, the method comprising:
forming a first region of the apparatus with logical circuits formed thereon and including a doped dielectric film, by:
growing a thermal oxide layer on a substrate;
depositing a doped dielectric film over the thermal oxide layer; and
forming a second region including a fluid port to receive the fluid, by:
selectively removing a portion of the doped dielectric film in the fluid port; and
protecting the doped dielectric film of the first region from the corrosive attributes of the fluid by depositing an un-doped dielectric film over the edge of the doped dielectric film.

9. The method of claim 8, including selectively removing the portion of the doped dielectric film in the fluid port using a selective mask and applying an etching process to the apparatus.

10. The method of claim 8, including selectively removing the portion of the doped dielectric film in the fluid port, by:
using a selective mask and a dry etch process, removing the doped dielectric film from the fluid port;
filling the fluid port with the un-doped dielectric film; and
removing a portion of the un-doped dielectric film in the fluid port.

11. The method of claim 8, including selectively removing the portion of the doped dielectric film in the fluid port, by using a mask to selectively etch the doped dielectric film.

12. A method of manufacturing an apparatus, the method comprising:
forming a monolithic integrated circuit with logical circuits formed thereon and including a doped dielectric film, by:
growing a thermal oxide layer on a substrate;
depositing the doped dielectric film over the thermal oxide layer; and
depositing a metal layer over the doped dielectric film; and
forming a portion of a microfluidic device, collocated on the apparatus with the monolithic integrated circuit, the portion of the microfluidic device including a fluid port, by:
removing the doped dielectric film in a location of the microfluidic device and including the fluid port, wherein the fluid port is defined by an edge of the doped dielectric film; and
protecting the doped dielectric film of the monolithic integrated circuit from corrosive attributes of the fluid by depositing an un-doped dielectric film over the edge of the doped dielectric film.

13. The method of claim 12, wherein forming the monolithic integrated circuit includes depositing a polysilicon layer over the thermal oxide and before the doped dielectric film.

14. The method of claim 12, wherein forming the monolithic integrated circuit includes:
depositing a polysilicon layer over the thermal oxide and before the doped dielectric film, the polysilicon layer including an overlay region of polysilicon extending beyond the edge of the doped dielectric film; and
removing the overlay region of polysilicon and the doped dielectric from the fluid port.

15. The method of claim 12, including selectively removing the portion of the doped dielectric film in the fluid port, by:
using a selective mask and an etch process, removing the doped dielectric film from the fluid port;
patterning the metal layer over the doped dielectric film; and
etching both the metal layer and doped dielectric film.
